(19) United States
(12) Patent Application Publication
(10) Pub. No.: US 2009/0051383 A1
(43) Pub. Date: Feb. 26, 2009

(54) Test Method and Production Method for a Semiconductor Circuit Composed of Subcircuits

(75) Inventors: Wolfgang Ruf, Friedberg (DE); Martin Schnell, Xi'An (CN)

Correspondence Address: JENKINS, WILSON, TAYLOR & HUNT, P. A., Suite 1200 UNIVERSITY TOWER, 3100 TOWER BLVD.,, DURHAM, NC, 27707, US

(73) Assignee: QIMONDA AG, MUNICH (DE)

(21) Appl. No.: 11/885,383

(22) PCT Filed: Mar. 4, 2005
(86) PCT No.: PCT/EP05/02311

§ 371 Date: Aug. 30, 2007

(51) Int. Cl. G01R 31/26; G06F 17/50

(52) U.S. Cl. 324/763; 716/4

(57) ABSTRACT

Test method and production method for testing a semiconductor circuit comprising a plurality of subcircuits. The semiconductor circuit is produced according to specification stipulations comprising a design based on a hardware description language for a functional implementation, a logic synthesis for a structural implementation, a layout design for a topological implementation and processing a semiconductor substrates in accordance with the layout design. A test pattern having test signal sequences is coupled into the semiconductor circuit and functional results are coupled out. Test signal lengths and/or test signal levels are selected from a previously generated test parameter list, wherein the test parameter list is generated during the logic synthesis.

The present invention relates to a test method for testing a semiconductor circuit composed of subcircuits, which test method serves in particular for testing newly produced memory devices. Furthermore, the invention relates to a sequential programme for a programmable memory tester for carrying out the test method according to the invention, and to a production method for a semiconductor circuit composed of subcircuits.

In the development and production of new integrated semiconductor circuits, in particular in memory production, a large proportion of this is taken up by so-called design analysis. In design analysis, finished processed semiconductor circuits are checked with regard to their functionality, that is to say whether they fulfil previously defined specification stipulations. If this is not the case, improvements have to be made in the design phase.

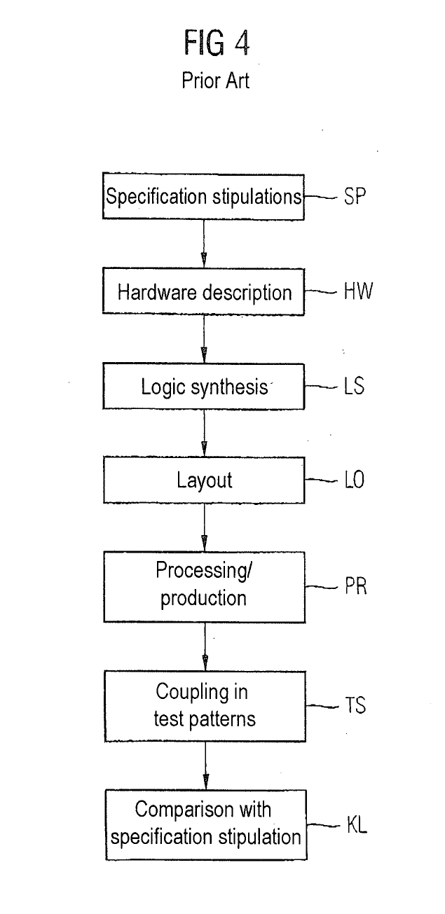

FIG. 4 illustrates by way of example a flow chart which describes a conventional design and the production of new semiconductor devices. In a first step SP, a system designer specifies the details of the product to be designed, or he defines the specification stipulations. This involves essentially defining the planned logical and electrical behaviour of the circuit to be designed. This includes for example temperature, frequency, supply voltage behaviour or, particularly in the case of memory devices, the input and output format of data, pin allocations and the dynamic behaviour of the semiconductor circuit. Such specification stipulations are often already defined as standard.

In a subsequent step HW, the semiconductor circuit is functionally characterized at the system level that is to say by description in the form of blocks, such as memories, processors, interfaces, I/O blocks, processes or communication protocols. This is done in a suitable hardware description language. A hardware description language characterizes behaviour and structure of the hardware system to be designed, but not the latter's geometry or explicit circuit parts. A hardware description language is similar to a programming language and contains parallel or sequential instructions and structure-describing elements, whereby a formal description of the system is effected, which description can additionally be simulated. At the system level, however, the description is always effected in an abstract and technology-independent fashion.

The logic properties of the circuit to be designed are characterized by operations and the transfer of data between registers. For this purpose, in the subsequent register transfer design, the system is characterized by an interconnection of register transfer modules. This RT description likewise consists in a technology-independent description of the circuit in a hardware description language (HDL) which serves as input information for the subsequent logic synthesis LS.

In the logic synthesis or the logic gate design, a transition takes place from the behaviour description by HDL to a structural description of the semiconductor circuit or of the hardware system. The corresponding logic gates are assigned to cells whose position is fixedly defined and which are subsequently linked by wiring resources. In a further refinement, a conversion from the logic level to the transistor level is effected by exchanging the logic gates for transistor netlists from a gate cell library. The logic synthesis LS therefore involves effecting a structural implementation of the initially functional design at the system level from the hardware description language, so that in principle an overall circuit arrangement is already present. The latter is usually composed modularly of many subcircuit arrangements. A memory cell or a read-write amplifier can be interpreted as a subcircuit arrangement, for example.

A layout step involves generating the layout information of the entire circuit design at the mask level. This topological implementation of the hardware is possible since a geometrical description of the transistors and their linkages at the mask level is already present in the gate cell library. The corresponding mask data are present in part as macros, and the result of the layout step LO is a topological implementation of the circuit arrangement in the form of mask data which can be described by polygon progressions and finally serve for mask production.

The designed semiconductor circuit can then be implemented as an integrated circuit in the processing or production step PR. The IC (Integrated Circuit) represents an electronic functional unit which has a multiplicity of electronic functional elements that are electrically and mechanically connected to one another by a common semiconductor substrate (chip) such as transistors, diodes, resistors, capacitors, etc., having dimensions in the micron and submicron range. The relevant process groups such as layer production, lithography, etching and doping are in this case defined by the masks of the layout design.

In order to ascertain whether the corresponding semiconductor chip meets the specification stipulations defined at the beginning, complicated tests are then necessary and, if appropriate, adaptations in the production steps, such as to the specification stipulations SP, the hardware description HW, the logic synthesis LS or the layout LO are necessary.

The design analysis, that is to say the measurement of the newly produced semiconductor chip, takes place by coupling in test patterns and coupling out functional results. In this case, the coupled-in test patterns are based on the specification stipulations, for example on a read/write operation during a memory test. A specification stipulation may then be for example a time stipulation for the read-out of data. If the corresponding produced memory device does not achieve the stipulation, it is generally rejected and corrections are made in the abovementioned steps SP, HW, LS, LO, PR.

Usually, only individual chips are tested on so-called bench testers, and the corresponding test patterns are constructed by design engineers. This is highly time-consuming and in practice prevents volume measurements from being carried out on many newly designed devices to be classified.

Therefore, it is an object of the present invention to provide a test method for testing a semiconductor circuit composed of subcircuits, which test method checks simply, rapidly and as far as possible a plurality of semiconductor circuits in parallel with regard to their specification stipulations. In this case, it is particularly desirable to obtain for the design analysis classification data of the tested chips which enable a simple improvement in the design or production steps.

This object is achieved by means of a test method in accordance with patent claim 1.

Accordingly, a test method for testing a semiconductor circuit composed of subcircuits is provided, the semiconductor circuit being produced by means of specification stipulations for the semiconductor circuit, by means of a design based on a hardware description language for the functional implementation of the specification stipulations at the system level, by means of a logic synthesis for the structural implementation of the functional design by means of electronic components to form subcircuit arrangements in an overall circuit arrangement of the semiconductor circuit, by means of a layout design for a topological implementation of the overall circuit arrangement with the electronic components on a semiconductor substrate and by means of a processing of the semiconductor substrate in accordance with the layout design for forming the semiconductor circuit.

The test method has the following test method steps for testing a specification function of the semiconductor circuit:
a) coupling in a test pattern, which comprises test signal sequences with respective test signal lengths and test signal levels, into the semiconductor circuit;
b) coupling out a functional result from the semiconductor circuit;
c) comparing the coupled-out functional result of the semiconductor circuit with a corresponding specification stipulation.

In this case, according to the invention, at least one selection of the test signal lengths and/or test signal levels for the test pattern is selected from at least one previously generated test parameter list, and the at least one test parameter list with values of test signal lengths and test signal levels for a subcircuit arrangement is generated during the logic synthesis.

An essential idea on which the invention is based consists in generating, as early as in the logic synthesis, test parameter lists which can subsequently be used advantageously during a check of the finished produced semiconductor circuit. A particular advantage of generating test parameter lists for the subcircuit arrangements consists, in particular, in the fact that in the logic synthesis, particularly critical situations for the subcircuit arrangement become known and corresponding test parameters, such as, for example, a specific sequence of signal lengths, for later tests can be stored. The test parameter lists which are generated early additionally allow the creation of automatic and flexible programming methods for the actual test methods for testing the specification functions. Furthermore, by means of an automated creation of the test patterns from the test parameter lists, a particularly large number of measurements are possible without development engineers having to intervene.

In one embodiment of the test method according to the invention, a respective test parameter list has internal voltage values of a semiconductor subcircuit which are to be set for a test pattern. It is also particularly advantageous if a test parameter list is generated for each subcircuit arrangement.

Thus, for example, in a preferred configuration of the semiconductor circuit to be tested as a memory device, it is possible to establish a list of internal reference voltage values for read/write amplifiers or comparators, said read/write amplifiers in each case representing semiconductor subcircuits or subcircuit arrangements.

Preferably, the test method according to the invention is carried out in parallel for testing identical semiconductor circuits. Consequently, identical semiconductor circuits implemented on an individual semiconductor wafer, for example, are tested in parallel. The test parameter lists generated early enable standardized method actions, whereby a particularly high throughput of tested semiconductor chips is obtained.

In a further preferred application of the method according to the invention, the method is carried out by means of a programmable memory tester for testing memory devices. In contrast to bench testers which are usually used and which can only take up individual new semiconductor devices produced, the use of a programmable memory tester enables a cost-saving alternative and also a simple and efficient programming of the same whilst utilizing the test parameter lists that are always generated according to the invention. Preferably, a plurality of test patterns are then also coupled into the semiconductor circuit successively using the test parameter lists from a selection of test parameter lists for testing a plurality of specification stipulations.

In a preferred development of the test method according to the invention, the semiconductor circuit has an internal test control device, and the semiconductor circuit can be put into a test mode by test control signals. In this case, in the test mode the test control device changes operating parameters of the subcircuit arrangements in order to identify tolerance ranges for said operating parameters. Furthermore, the test control signals are generated in a manner dependent on the test parameters.

By way of example, the operating parameters may have internal voltages, reference potentials or signal edge shapes. Possible operating parameters, such as the internal voltages in subcircuit arrangements, can be fixed or determined in practice only during the logic synthesis.

Furthermore, the invention provides a sequential programme for a programmable memory tester for carrying out the test method according to the invention for testing at least one semiconductor memory device comprising the programme steps of:
a) carrying out a first standard test sequence by means of a first predetermined standard test pattern for testing first specification stipulations by coupling in the standard test pattern, coupling out the corresponding functional result and comparing the coupled-out functional result with the specification stipulations;
b) repeating the first standard test sequence by means of an altered standard test pattern, a respective standard test pattern being constructed in such a way that dummy data areas are provided for inserting test parameters from the test parameter lists;
c) classifying the tested semiconductor memory devices on the basis of the comparison results of the various standard test sequences as fulfilling or not fulfilling the specification stipulations.

The sequential programme according to the invention provides for inserting the test parameter lists generated during the logic synthesis at specific locations having dummy data areas. In this case, it is particularly favourable if the test parameter lists are already produced in a format appropriate for the sequential programme. The standardized form of positions of the dummy data areas makes it possible to test many newly designed and produced semiconductor circuits rapidly and in a standardized manner. The classification can then also take place in such a way that specific tolerances in the specification stipulations define a plurality of classes of semiconductor circuits.

Preferably, further standard test sequences are provided, the standard test patterns in each case being constructed in such a way that dummy data areas are provided for inserting test parameters from the test parameter lists. By way of example, the standard test sequences, for testing memory devices, may comprise a read/write test, precharge test and/or a refresh test.

It is furthermore advantageous that operating parameters of a subcircuit arrangement are changed in each case prior to a programme step for a standard test sequence, in the sequential programme provision being made in each case of dummy data areas for inserting respective operating parameters from the test parameter lists. By way of example, operating parameters of this type may be reference voltage values for comparators when reading out data from memory cells. The specification of graduated reference voltage values of this type takes place most expediently during the logic synthesis in the form of the test parameter lists.

The invention additionally provides a production method for a semiconductor circuit composed of subcircuits comprising the following production method steps:
a) providing specification stipulations for the semiconductor circuit;
b) describing the specification stipulations in a design in a hardware description language for the functional implementation of the specification stipulations at the system level;
c) carrying out a logic synthesis for the structural implementation of the functional design in the hardware description language by means of electronics components to form subcircuit arrangements in an overall circuit arrangement of the semiconductor circuit;
d) generating test parameter lists with values of operating parameters, test signal lengths and test signal levels for the subcircuit arrangements;
e) generating a layout design for a topological implementation of the overall circuit arrangement with the electronic components on a semiconductor substrate;
f) processing the semiconductor substrate in accordance with the layout design for forming the semiconductor circuit;
g) coupling in a plurality of test patterns, which comprise test signal sequences with respective test signal lengths and test signal levels, into the semiconductor circuit, at least one selection of the test signal lengths and/or test signal levels for the test patterns being selected from the test parameter lists;
h) coupling out functional results from the semiconductor circuit;
i) comparing the coupled-out functional results of the semiconductor circuit with corresponding specification stipulations; and
j) classifying the semiconductor circuit.

An essential idea on which the production method according to the invention is based consists in compiling, as early as during the logic synthesis, items of information or test parameter lists which contain, in particular, operating parameters for the subcircuit arrangement. Usually, parameters of this type are not documented and cannot be utilized during a later classification or during a later test of the already formed and designed semiconductor device. According to the invention, however, it is particularly expedient to generate the test parameter lists at this early point in time of development. As a result, during a later test, a structured coupling in of different test patterns which are based on the test signal lengths and levels assembled in the test parameter lists is possible. This affords the possibility, in particular, of generating, during the test of the semiconductor circuit, large, standardized test data sets which can be evaluated in a simple manner. Classifications of the tested semiconductor circuits which determine various qualities of semiconductor circuits are also possible in this case. Usually, developed and produced semiconductor circuits had to be tested individually on so-called bench testers, which are costly and which, moreover, only allow individual measurements, as a result of which the measurement times are long. The production method according to the invention permits, however, volume measurements of many semiconductor circuits produced.

The test parameter lists are advantageously stored in test parameter list files. The latter may have preferred data structures which can be adapted simply to sequential programmes for corresponding automated test apparatuses.

In this case, it is furthermore advantageous that a plurality of identical semiconductor circuits are formed in parallel on a common semiconductor substrate and production steps g)-j) are carried out in parallel by means of a programmable test apparatus.

Advantageously, deviations of the coupled-out functional results from the specification stipulations in the case of various semiconductor circuits from among the semiconductor circuits formed on the common semiconductor substrate are compared with one another in order to identify systematic defects in the processing of the semiconductor substrate.

The production method according to the invention is particularly suitable for producing memory devices, programmable memory testers being used for checking the specification stipulations.

Further advantageous configurations of the invention are the subject matter of the sub claims and of the following description of the exemplary embodiments with reference to the accompanying figures, in which:

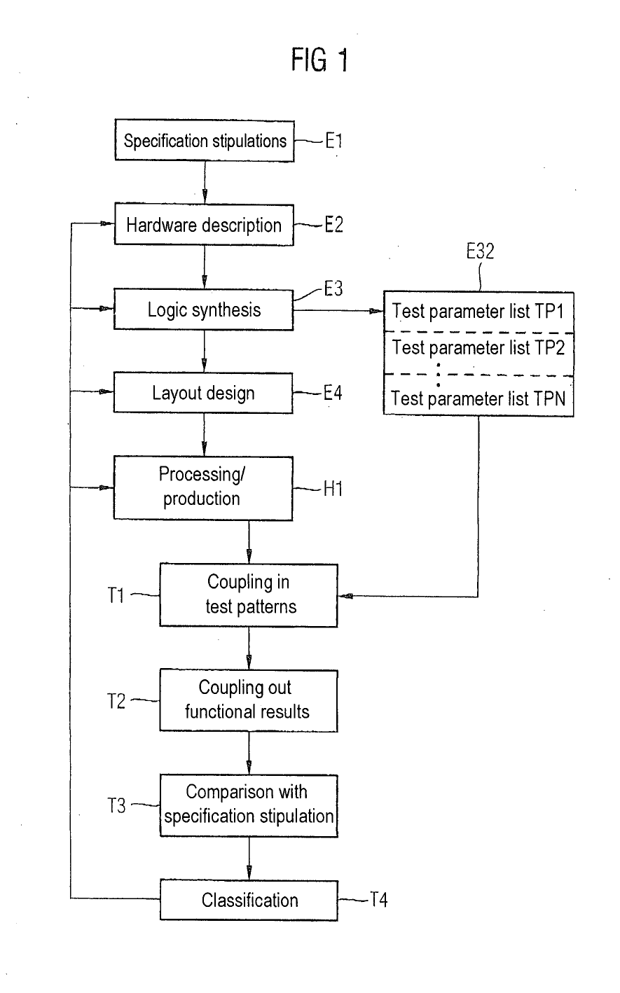

FIG. 1 shows a schematic flow chart of the production and test method according to the invention;

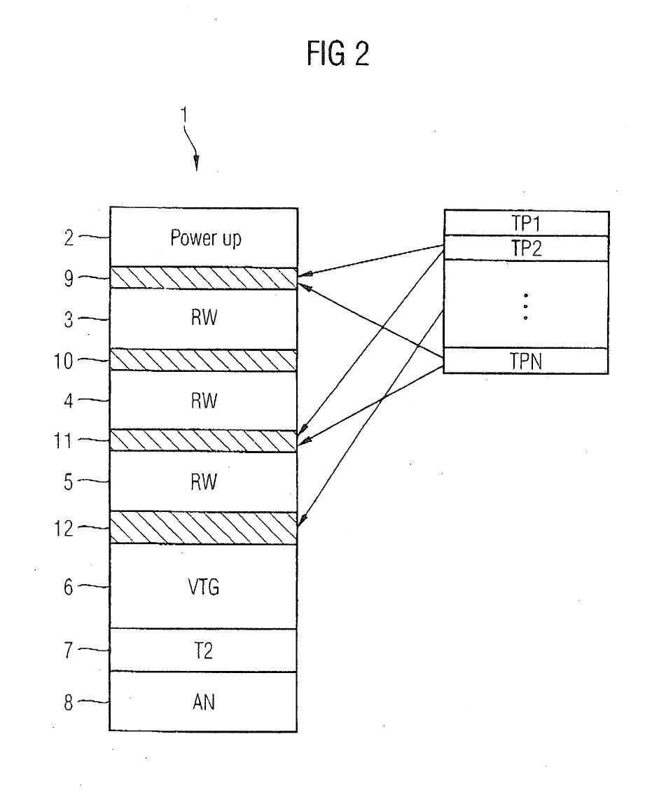

FIG. 2 shows a schematic illustration of a sequential programme according to the invention;

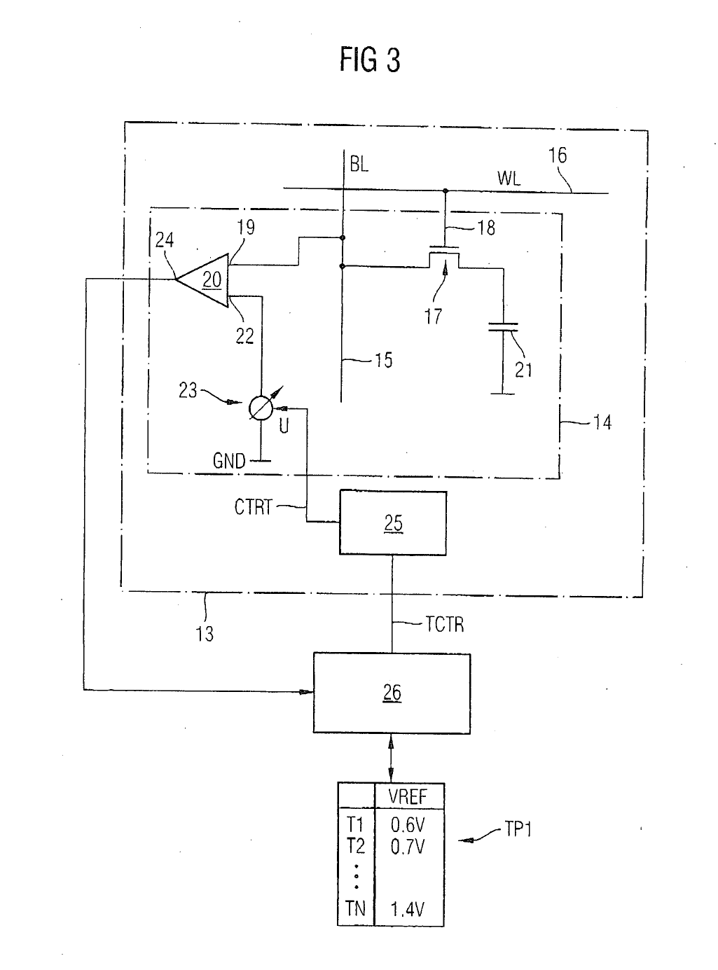

FIG. 3 shows an example of a test according to the invention of a subcircuit arrangement; and

FIG. 4 shows a flow chart for designing semiconductor devices according to the prior art.

Identical or functionally identical elements have been provided with identical reference symbols in the drawings.

FIG. 1 illustrates a schematic flow chart of the production and test method according to the invention.

In a first method step E1, specification stipulations, that is to say the planned logical and electrical behaviour of the circuit to be designed, are defined. By way of example, this includes temperature, frequency, supply voltage or delayed behaviour. In the design of semiconductor memories, specification stipulations are frequently documented in the form of standards for, for example, DRAM, FRAM, MRAM, flash or other memory products.

In a subsequent step E2, the specification stipulations are functionally implemented in the form of a hardware description language. This is done at the so-called system level, at which the characteristics of the system or of the semiconductor circuit to be designed are described in the form of blocks, memories, processors or interface units. Furthermore, at an algorithmic level, which is likewise counted as part of step E2, the system is described by algorithms such as function, procedures and processes. Finally, the register transfer level is reached, at which the circuit is described by operations, for example addition, and the transfer of the data to be processed between registers.

Subsequent step E3 of logic synthesis involves performing a structural implementation of the functional design from the hardware description by means of electronic components. This is generally done in the form of subcircuit arrangements which ultimately construct the overall circuit arrangement of the semiconductor circuit. During the logic synthesis, logical combinations and their temporal behaviour are implemented in the form of components, such as transistors, resistors and capacitances. Individual modules or subcircuit arrangements are already described by electronic components at this level.

At the same time as the logic synthesis, the test parameter list TP1, TP2, TPN is designed for each subcircuit arrangement in the step E32. Said test parameter lists contain characteristic operating parameters for the individual subcircuit arrangements. By way of example, this may be a specific voltage which is to be present at an access transistor for a memory cell. Furthermore, said test parameter lists may also have data which are generated characteristically by the subcircuit arrangements during the operation of the overall circuit arrangement.

During the logic synthesis, the development engineer can particularly expediently assess critical parameters and store them in the form of test parameter lists as files.

In the further production method a layout design E4 is then constructed as a topological implementation of the overall circuit arrangement with the corresponding electronic components on a semiconductor substrate. The layout predetermines the geometrical and topological arrangement of the individual components on the semiconductor substrate for the subsequent mask products.

A processing of the semiconductor substrate H1 for forming the semiconductor circuit takes place in accordance with the layout design or according to the masks produced. Customary process actions such as layer production, lithography, etching and doping are performed for this purpose.

In order to test the functionality of the corresponding semiconductor device produced, in a first test step T1, a test pattern with test signal sequences and test signal lengths and levels is coupled into the semiconductor circuit. In this case, the corresponding test signal lengths or test signal levels for the test patterns are generated from the corresponding test parameter lists. This is expedient since the test parameter lists generated during the logic synthesis supply the particularly expedient operating parameters and test parameters for the subcircuit arrangement.

Afterwards, in a further test step T2, functional results are coupled out from the semiconductor circuit.

The comparison step T3 involves comparing the coupled-out functional results of a semiconductor circuit with the corresponding specification stipulations.

The tested semiconductor circuits can be classified T4 from deviations of the coupled-out functional results from the specification stipulations. The fact that, according to the invention, operating and test parameters are produced in the test parameter lists during the logic synthesis E3 means that errors or deviations between the respective coupled-out functional result and the specification stipulations can be localized well. By way of example, from the multiplicity of comparison results for different test parameters or operating parameters of a subcircuit arrangement, it is possible to identify which electronic components were possibly produced defectively. The hardware description E2, the logic synthesis E3, the layout design E4 or the processing and production steps H1 can thus be adapted in order to eliminate such defects.

FIG. 2 illustrates an exemplary sequential programme 1 for use in a programmable tester apparatus. The test and production method according to the invention will be explained below using the example of designed and produced semiconductor memories. The sequential programme 1 provides a plurality of standard test sequences 2, 3, 4, 5, 6, 7, for example firstly a power-up of the semiconductor memory device to be tested being provided.

In customary programmable memory testers, contact is made with the semiconductor devices to be tested by means of test heads via tester channels. Test signals are coupled in via said tester channels. It is likewise conceivable for contact to be made with a produced semiconductor wafer with circuit arrangements formed thereon.

The sequential programme 1 according to the invention furthermore provides dummy data areas 9, 10, 11, 12, into which the test parameter lists TP1, TP2, TPN generated during the logic synthesis can be inserted. In this case, the dummy data areas and also the corresponding test parameter lists are supplied in a suitable data format. By way of example, the test parameter lists can be stored as test parameter list files during the logic synthesis. After the power-up of the memory device to be tested, a first test parameter list is read in and a read/write test 3 is carried out. Afterwards, a further test parameter list, which sets altered operating parameters by comparison with the first read/write test 3 for a subsequent second read/write test 4, is provided in a dummy data area 10 of the sequential programme 1. The altered operating parameters may be for example graduated values of an internal supply voltage. The respective coupled-out comparison results are then stored.

There follows a further standard test sequence for the read/write test, test parameters or operating parameters from one of the test parameter lists TP1, TP2, . . . TPN once again being inserted in a dummy data area 11 beforehand.

In a subsequent standard test sequence 6, internal voltages of the memory devices to be tested are measured, by way of example. This is done once again with the aid of a test parameter list that was inserted beforehand into a dummy data area 12 kept available.

Further standard test sequences 7 subsequently ensue and an analysis of the stored test results 8 finally ensues. In the last programme part of the analysis 8, the tested memory device can then be classified or, if defects have occurred, for example, the cause of the defects can be localized since the test parameter lists are in each case allocated to subcircuit arrangements in the semiconductor memory to be tested. In the case of a change in test parameters of individual subcircuit arrangements and a simultaneously altered test result or comparison result, it is thus possible to deduce defects in the corresponding subcircuit arrangement.

FIG. 3 schematically shows the linkage of a subcircuit arrangement in a semiconductor memory and test parameter lists for a memory test according to the invention.

A formed semiconductor device 13 is provided, which here has a semiconductor subcircuit 14. The subcircuit arrangement 14 is a memory cell, for example, which is coupled to a bit line 15 and a word line 16, and also a sense amplifier 20 assigned to the respective bit line 15. For this purpose, an access transistor 17 having a controllable path and a control terminal 18 is provided, the control terminal being connected to the word line 16 and the controllable path being connected to a storage capacitor 21 in series between the bit line 15 and ground GND. Each bit line is assigned a sense amplifier, or here a comparator 20, which is likewise assigned to the illustrated exemplary subcircuit arrangement 14 in FIG. 3. A first input 19 of the comparator 20 is connected to the bit line 15, and a second input 22 of the comparator is connected to a reference potential VREF. The reference potential VREF is supplied by a controllable reference voltage source 23. In order to read out the memory content of this memory cell 14, the voltage present at the first input 19 of the comparator is compared with the reference voltage VREF, the voltage present at the first input 19, with the controllable path of the access transistor 17 being open, depending on the charge accumulated in the storage capacitor. If the voltage at the first input 19 is higher than that of the second input 22, the output 24 of the comparator supplies for example a first logic level and otherwise a second logic level.

The semiconductor memory device 13 has a test control device 25, which controls the reference voltage source 23 by means of control signals CTRT. The reference voltage VREF can thus be regarded as an operating parameter or test parameter. A test parameter list TP1 having graduated values for the reference voltage VREF of 0.6 to 1.4 V was generated during the design in the logic synthesis of the corresponding semiconductor memory 13. T1-TN, by means of which the corresponding reference voltage VREF is defined, serve as test parameters here.

During a test of the memory device 13 by a programmable tester device 26, the latter supplies for example test control signals TCTR to the test control device 25. Thus, in various standard test sequences, for example as in read/write tests illustrated in FIG. 2, the memory tester 26 controls the test control device in such a way that different reference voltages VREF are generated by the reference voltage source 23 in various read/write tests. Consequently, it is possible to check, on the one hand, how robustly the memory cell reacts to fluctuations in the reference voltage, and it is possible to ascertain, on the other hand, whether the memory cell is functional at a nominal reference voltage value or a reference voltage value specified by the specification stipulations.

For the test according to the invention, it is necessary in this case for the corresponding test parameters T1-TN or operating parameters already to be stored in tabular form in the design phase. This table or test parameter list TP1 enables specification functions to be tested rapidly and efficiently during the later design analysis or the functional test of the semiconductor circuit 13 formed.

The present invention therefore provides a production and test method for semiconductor circuits composed of subcircuits which makes it possible to test a multiplicity of semiconductor circuits in parallel and, on account of the test parameter lists established early, to localize defects during the design of the corresponding semiconductor circuit device. By means of a standardized form of test parameter lists, it is possible to use tester devices that are programmable by means of particularly expedient sequential programme controls. A high analysis throughput of semiconductor circuits and short analysis times can thus be obtained. The test and production method according to the invention enables volume measurements for the design analysis and the development of standardized sequential programmes for memory testers of this type.

### LIST OF REFERENCE SYMBOLS

SP Specification stipulations
HW Hardware description
LS Logic synthesis
LO Layout
PR Processing
TS Coupling in test patterns
KL Comparison with specification stipulation
E1 Specification stipulations
E2 Hardware description
E3 Logic synthesis
E32 Generating test parameter lists
E4 Layout design
H1 Processing the semiconductor substrate
T1 Coupling in test patterns
T2 Coupling out functional results
T3 Comparison with specification stipulations
T4 Classification
TP1, TP2 to TPN Test parameter list
1 Sequential programme
2-7 Standard test sequence
19,11,12 Dummy data area
8 Analysis
13 Semiconductor memory
14 Subcircuit arrangement, memory cell
15 Bit line
16 Word line
17 Access transistor
18 Control terminal
19 Input
20 Comparator
21 Capacitor
22 Input
23 Reference voltage source
24 Output
25 Test control device
26 Memory tester
T1-TN Test parameter
CTRT Control signals
TCTR Control signals
VREF Reference voltage

What is claimed is:

1. A test method for testing a semiconductor circuit comprising subcircuits and being fabricated by means of:
specification stipulations for the semiconductor circuit;
a design based on a hardware description language for a functional implementation of the specification stipulations at a system level;
a logic synthesis for a structural implementation of the functional design by means of electronic components to form subcircuit arrangements in an overall circuit arrangement of the semiconductor circuit;
a layout design for a topological implementation of the overall circuit arrangement having the electronic components on a semiconductor substrate; and by means of
processing of the semiconductor substrate in accordance with the layout design for forming the semiconductor circuit;
comprising the following test method steps for testing a specification function of the semiconductor circuit:
a) coupling in a test pattern, said test pattern comprising test signal sequences with respective test signal lengths and test signal levels, into the semiconductor circuit;
b) coupling out a functional result from the semiconductor circuit;
c) comparing the coupled-out functional result of the semiconductor circuit with a corresponding specification stipulation;
wherein at least one selection of the test signal lengths and/or test signal levels for the test pattern is selected from at least one previously generated test parameter list; and wherein
said at least one test parameter list comprises values of test signal lengths and test signal levels for a subcircuit arrangement said test parameter list being generated during said logic synthesis.

2. The test method according to claim 1,
wherein said test parameter list corresponding to a test pattern comprises internal voltage values of at least one of said semiconductor subcircuits.

3. The test method according to claim 1,
wherein a test parameter list is generated for each subcircuit arrangement.

4. The test method according to claim 1,
wherein said semiconductor circuit to be tested forms a memory device.

5. The test method according to claim 1,
wherein the method is carried out in parallel for testing a plurality of identical semiconductor circuits.

6. The test method according to claim 1,
wherein the method is carried out by means of a programmable memory tester for testing memory devices.

7. The test method according to claim 1,
wherein a plurality of test patterns are coupled into said semiconductor circuit successively using the at least one test parameter list from a selection of test parameter lists for testing a plurality of specification stipulations.

8. The test method according to claim 1,
wherein said semiconductor circuit comprises an internal test control device, said semiconductor circuit can be put into a test mode by test control signals, wherein in the test mode the test control device changes operating parameters of said subcircuit arrangements for identifying tolerance ranges for the operating parameters, and wherein said test control signals are generated as a function of said at least one test parameter list.

9. The test method according to claim 8,
said operating parameters comprise internal voltages, reference potentials or signal edge shapes.

10. A programme for a programmable memory tester for carrying out a test method for testing at least one semiconductor memory device according to claim 1 comprising the programme steps of:
carrying out a first standard test sequence by means of a first predetermined standard test pattern for testing first specification stipulations by coupling in said first standard test pattern, coupling out a corresponding functional result and comparing the coupled-out functional result with the specification stipulations;
repeating said first standard test sequence by means of an altered standard test pattern, a respective standard test pattern or altered standard test pattern being constructed in such a way that dummy data areas are provided for inserting test parameters from said test parameter lists; and
classifying the at least one tested semiconductor memory device on the basis of the comparison results of the standard test sequences as fulfilling or not fulfilling the specification stipulations.

11. The programme according to claim 10,
wherein further standard test sequences are provided, corresponding further standard test patterns being constructed in such a way that dummy data areas are provided for inserting test parameters from the test parameter lists.

12. The programme according to claim 10,
wherein the standard test sequences comprise a read/write test, precharge test and/or a refresh test for testing memory devices.

13. The programme according to claim 10,
wherein operating parameters of a subcircuit arrangement are changed in each case prior to executing a programme step for a standard test sequence, said programme comprising dummy data areas for inserting respective operating parameters from the at least one test parameter list.

14. A method for fabricating a semiconductor circuit comprising subcircuits, the method comprising:
a) providing specification stipulations for said semiconductor circuit;
b) describing the specification stipulations in a design in a hardware description language for a functional implementation of said specification stipulations on a system level;
c) carrying out a logic synthesis for a structural implementation of the design in the hardware description language by means of electronic components to form a plurality of subcircuit arrangements in an overall circuit arrangement of said semiconductor circuit;
d) generating test parameter lists comprising values of operating parameters, test signal lengths and test signal levels for the plurality of subcircuit arrangements;
e) generating a layout design for a topological implementation of said overall circuit arrangement with the electronic components on a semiconductor substrate;
f) processing the semiconductor substrate in accordance with said layout design for forming said semiconductor circuit;
g) coupling in a plurality of test patterns, which comprise test signal sequences with respective test signal lengths and test signal levels, into said semiconductor circuit, at least one selection of the test signal lengths and/or test signal levels for the test patterns being selected from said test parameter lists;
h) coupling out functional results from the semiconductor circuit;
i) comparing said coupled-out functional results of the semiconductor circuit with corresponding specification stipulations; and
j) classifying the semiconductor circuit.

15. The method according to claim 14,
wherein said test parameter lists are stored in test parameter list files.

16. The method according to claim 14,
wherein a plurality of identical semiconductor circuits are formed in parallel on a common semiconductor substrate and steps g)-j) are carried out in parallel by means of a programmable test apparatus.

17. The method according to claim 16,
comprising comparing deviations of the coupled-out functional results from the specification stipulations of various semiconductor circuits from among the semiconductor circuits formed on the common semiconductor substrate with one another for identifying systematic defects in the processing of the semiconductor substrate.

18. The method according to claim 14,
comprising classifying said formed and tested semiconductor circuits depending on a measure for a deviation from said specification stipulations.

19. The method according to claim 14,
wherein if a deviation of the coupled-out functional results from the specification stipulations occurs correcting at least one of the production steps b)-f) for reducing the respective deviation.

20. The method according to claim 14,
wherein memory devices are fabricated and programmable memory testers are used.
